(19) United States
(12) Patent Application Publication
(10) Pub. No.: US 2018/0130330 A1
(43) Pub. Date: May 10, 2018

(54) Wireless Reporting of Facility Problems

(71) Applicant: Monica Martino, Allen, TX (US)

(72) Inventor: Monica Martino, Allen, TX (US)

(21) Appl. No.: 15/584,427

(22) Filed: May 2, 2017

Related U.S. Application Data
(60) Provisional application No. 62/420,203, filed on Nov. 10, 2016.

(51) Int. Cl. G08B 21/18; G08B 25/10; G01L 19/12; G01M 3/04; G01R 19/165; G01J 1/42

(52) U.S. Cl. CPC G08B 21/182; G08B 25/10; G01J 1/42; G01M 3/04; G01R 19/165; G01L 19/12

(57) ABSTRACT

A water leak detector providing a water leak signal, a wireless networking microcontroller coupled to the water leak detector, the wireless networking microcontroller sending alarms based on the input from the water leak detector, a power conditioner coupled to the wireless networking microcontroller to provide a conditioned power signal to the wireless networking microcontroller and a programming interface coupled to the wireless networking microcontroller, wherein the programming interface provides programming signals to the wireless networking microcontroller to set predetermined alarm thresholds. The water leak detector receives the water leak signal and sends notification to a person or system for intervention without the need for a dedicated communications hub.

### FIELD

The present solution relates to the wireless reporting of facility issues and specifically to the wireless reporting of water leaks.

### BACKGROUND

Wireless water leak detection allows the owner of a facility the ability to quickly detect a water leak and may dramatically reduce the response time and possible water damage resulting from the leak.

Current water leak detection systems have a direct line connection to a reporting transmitter, this direct line may be shorted out during a water leak and may not alert a structure's owner of the issue, which may result in a delayed response.

Therefore, what is needed is a wireless reporting of facility issues and report them wirelessly to a responsible party.

### BRIEF SUMMARY

In one embodiment, a system comprises one or more of: a water leak detector providing a water leak signal, a wireless networking microcontroller coupled to the water leak detector, the wireless networking microcontroller sending alarms based on the input from the water leak detector, a power conditioner coupled to the wireless networking microcontroller to provide a conditioned power signal to the wireless networking microcontroller and a programming interface coupled to the wireless networking microcontroller, wherein the programming interface provides conditioned programming signals to the wireless networking microcontroller to set predetermined alarm thresholds so that the system alarms when the predetermined alarm thresholds are exceeded.

In another embodiment, a system comprises one or more of: a facilities failure detector providing a conditioned failure signal, a wireless networking microcontroller coupled to the facilities failure detector, the wireless networking microcontroller sending alarms based on the input from the facilities failure detector, a power conditioner coupled to the wireless networking microcontroller to provide a conditioned power signal to the wireless networking microcontroller and a programming interface coupled to the wireless networking microcontroller, wherein the programming interface provides conditioned programming signals to the wireless networking microcontroller to set predetermined alarm threshold for the failure signal, so that the system alarms when the predetermined alarm thresholds are exceeded.

In a further embodiment, a method comprises one or more of: receiving conditioned failure signals from a facilities failure detector for a structure, determining whether the failure signals are within acceptable predetermined limits and sending a wireless signal alarm if the failure signals are outside of the acceptable predetermined limits.

### BRIEF DESCRIPTION OF THE DRAWINGS

FIG. 1 illustrates a first example architecture view of the present solution and its components.

FIG. 2 illustrates a second example architecture view of the present solution and its components.

FIG. 3 illustrates a third example architecture view of the present solution and its components.

FIG. 4 illustrates an example method, depicting the signal flow between the wireless networking microcontroller and the feed in components.

### DETAILED DESCRIPTION

It will be readily understood that the instant components, as generally described and illustrated in the figures herein, may be arranged and designed in a wide variety of different configurations. Thus, the following detailed description of the embodiments of at least one of a method, apparatus, and system, as represented in the attached figures, is not intended to limit the scope of the application as claimed, but is merely representative of selected embodiments.

The instant features, structures, or characteristics as described throughout this specification may be combined in any suitable manner in one or more embodiments. For example, the usage of the phrases “example embodiments”, “some embodiments”, or other similar language, throughout this specification refers to the fact that a particular feature, structure, or characteristic described in connection with the embodiment may be included in at least one embodiment. Thus, appearances of the phrases “example embodiments”, “in some embodiments”, “in other embodiments”, or other similar language, throughout this specification do not necessarily all refer to the same group of embodiments, and the described features, structures, or characteristics may be combined in any suitable manner in one or more embodiments.

In addition, while the term “signal” may have been used in the description of embodiments, the application may be applied to many types of network data, such as, packet, frame, datagram, etc. The term “signal” also includes packet, frame, datagram, and any equivalents thereof. Furthermore, while certain types of messages and signaling may be depicted in exemplary embodiments they are not limited to a certain type of message, and the application is not limited to a certain type of signaling.

The present solution relates to wireless reporting of facilities failures, specifically the wireless reporting of water leaks. The wireless reporting may be by one of any number of signaling structures such as ZigBee, WiFi, Bluetooth, Bluetooth Low Energy, WiMax and the like. The system has the ability to receive a sensor or detector signal and send a notification to either a human or machine for intervention. The system requires no dedicated hub to connect to the internet for communication, any wireless signal such as WiFi is sufficient for communication connection. ZigBee is a communication protocol that transceives a ZigBee signal at 915 MHz, it is an IEEE 802.15.4-based specification used to create personal area networks with low-power digital radios. WiFi is a communication protocol that that transceives a WiFi signal at 2.4 gigahertz ultra-high frequency (UHF) and 5 gigahertz super-high frequency (SHF) industrial, scientific, medical (ISM) radio bands and is used to create wireless local area networking with devices based on the IEEE 802.11 standards. Bluetooth is a communication protocol that transceives a Bluetooth signal at 2.4 to 2.485 GHz frequency bands, for creating personal area networks and is based on the IEEE 802.15.1 standard. Bluetooth low energy is a communication protocol that transceives a Bluetooth Low Energy signal to create a wireless personal area network for reduced energy consumption while maintaining a similar communication range as Bluetooth. WiMax is a communication protocol that transceives a WiMax signal based on IEEE 802.16 and is designed to provide 30-40 Mbit per second data rates and is designed to operate at 2.4 GHz, 3 GHz, 5 GHz, and 60 GHz.

During device setup the detector communication switches from a router to a client. This client switching simplifies communication in that the system sends data packets and does not receive external communication data packets. This simplification in communication from router to client disallows hijacking the detector by an external communication source.

### A First System Example

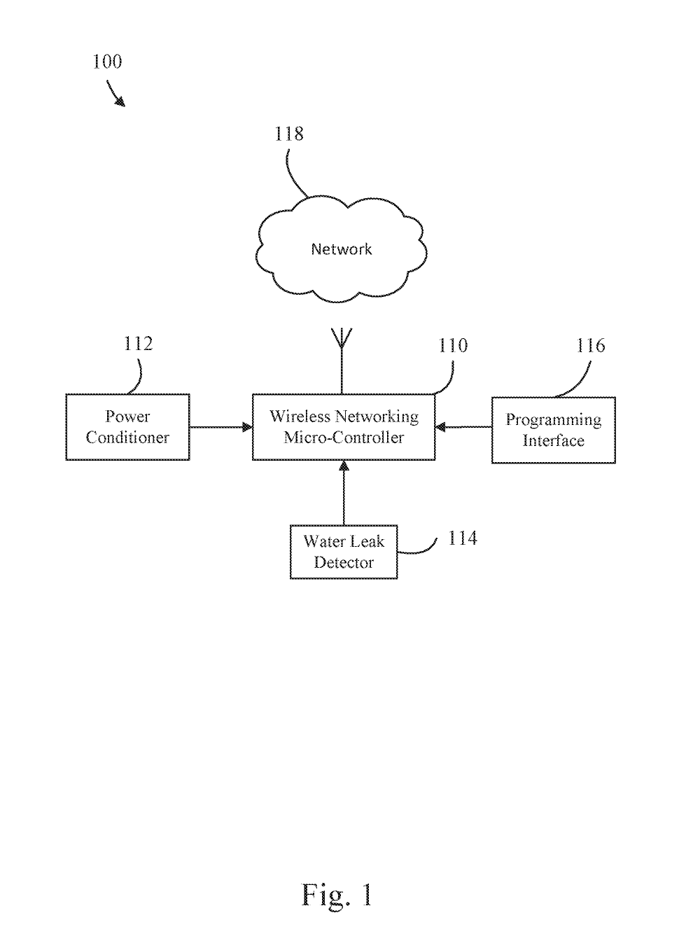

FIG. 1 depicts a first example embodiment of the system 100. The center of the system is the wireless networking microcontroller 110 communicating with a network 118. The wireless networking microcontroller is programmable to be able to set the trigger alarm thresholds and accepts inputs from a detector such as the water leak detector 114. The wireless networking microcontroller may be an ESP8266EX or the like and may be a system on a chip having an embedded memory, central processing unit and wireless transceivers. In this example the ESP8266EX wirelessly communicates via WiFi.

The water leak detector 114 may be as simple as two pins that come into contact with a water source to short the pins, and may be connected to a Schottky diode voltage clamp and an ultra-low leakage load switch such as a TI TPS22860 or the like.

The ultra-low leakage load switch may be coupled to a logic gate such as a TI SN74AUP1G32 Low-Power Single 2-Input Positive-OR Gate or the like, to condition the logic signal for input into the wireless networking microcontroller 110.

The programming interface 116 may be as simple as Schottky diode voltage clamps coupled to the transmit and receive pins of the wireless networking microcontroller.

The power conditioner 112 may be a direct current to direct current converter such as a BU34DV7NUX, 1.8V to 5.5V, 300 mA 1ch Synchronous Boost DC/DC Converter coupling the power source to the wireless networking microcontroller 110.

### A Second System Example

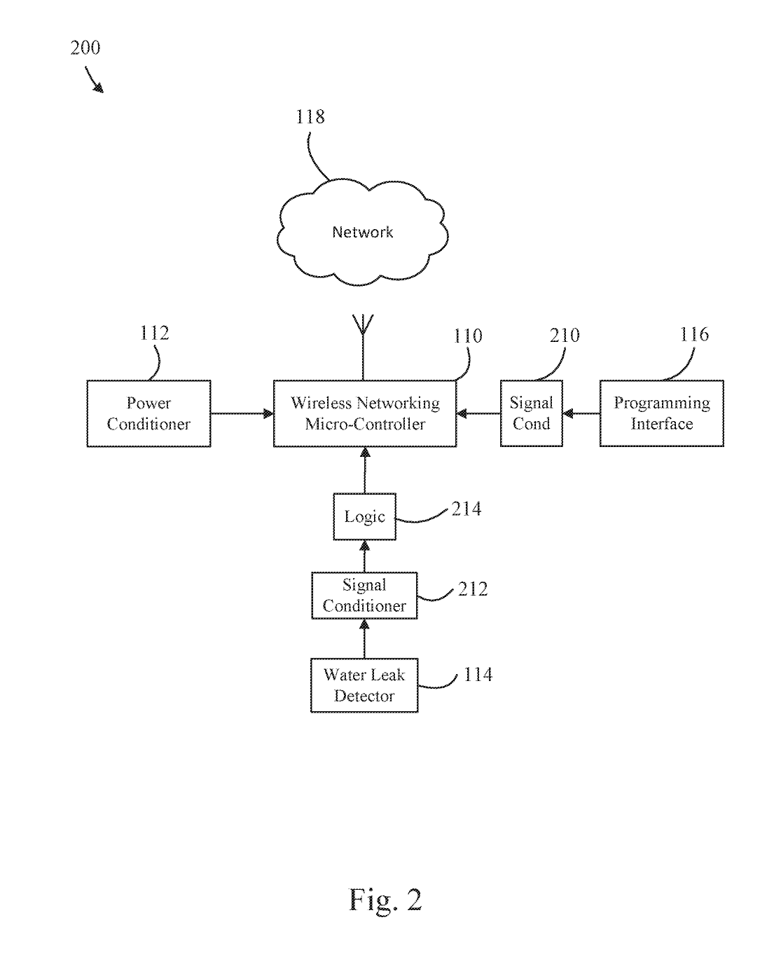

FIG. 2 is a modification 200 of FIG. 1 in which signal conditioning 210 from the signal conditioner clamps the voltage of the programming interface and conditions the signal 212 of the water leak detector 114. The signal conditioning 210/212 may be provided by series connected Zener diodes acting as voltage clamps.

The logic module 214 may comprise a switch, such as the ultra-low leakage load switch such as a TI TPS22860 or the like and may also be coupled to a logic gate such as a TI SN74AUP1G32 Low-Power Single 2-Input Positive-OR Gate or the like which feeds a logic signal into the wireless networking microcontroller 110.

### A Third System Example

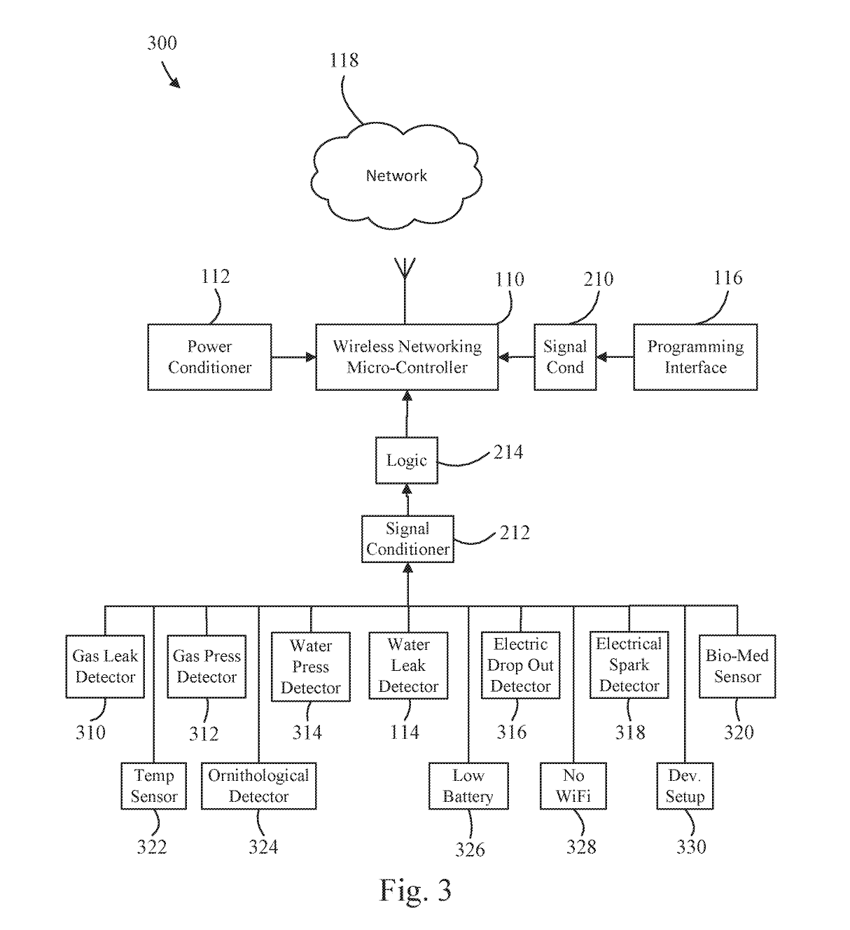

FIG. 3 is a modification 300 of FIG. 2 in which additional facility failure detectors such as a gas leak detector 310, a gas pressure detector 312, a water leak detector 114, a water pressure detector 314, an electrical voltage drop out detector 316 and an electrical spark detector 318, a bio-medical alarm sensor 320, a temperature sensor 322 and an ornithological detector 324.

The gas leak detector 310 may be for example a photoionization detector (PID) measuring volatile organic compounds and the like. The gas leak detector may set an alarm if a gas leak threshold is exceeded indicating a possible hazard.

The gas pressure detector 312 converts pneumatic pressure into an analog electrical signal such as a strain-gage base transducer and the like. As an example if pressures of 2 PSIG, 5 PSIG or the like are sensed, exceeding a gas pressure threshold, an alarm may be set.

The water pressure detector 314 converts hydraulic pressure into an analog electrical signal such as a strain-gage base transducer and the like. Example water pressure thresholds may be set according to municipal water pressure norms, the thresholds may be set at 60 psi, 80 psi, 150 psi and the like.

The electrical drop out detector 316 detects a drop in voltage in an electrical power supply system such as a brownout. The voltage threshold of the electrical voltage drop out may be set by the user as 2 volts, or the like.

The electrical spark detector 318 may contain a photo diode element that detects a spark infrared radiation. Additionally, sparks may be detected by an arc-fault sensor and the spark threshold may be set by the user.

The bio-medical alarm sensor 320 may contain a transceiver to receive a health condition alarm from a fall sensor, a low glucose sensor, a cessation of movement detector and the like.

The temperature sensor 322 may contain a thermocouple to measure the temperature of the residence.

The ornithological detector 324 may contain an optical sensor or microphone to detect the presence of a bird within the residence.

The system may also provide notification of events other than facility issues such as low system power 326, loss of a wireless signal 328, device setup 330 and the like.

### A Method Example

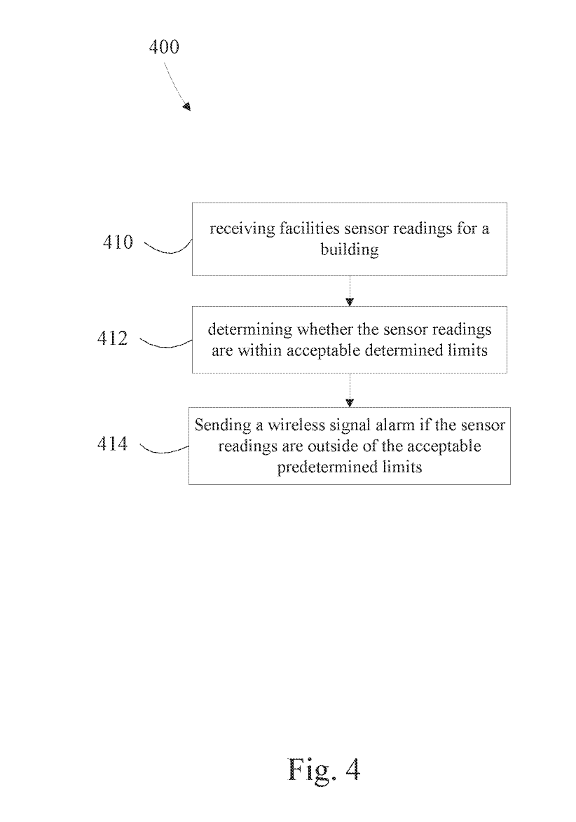

FIG. 4 depicts an example method 400 comprising receiving conditioned failure signals 410 from a facilities failure detector for a structure. The failure detectors may comprise sensors such as a gas leak detector 310, a gas pressure detector 312, a water leak detector 114, a water pressure detector 314, an electrical voltage drop out detector 316 and an electrical spark detector 318 from FIG. 3.

The method further comprises determining 412 whether the failure signals are within acceptable determined limits. The wireless networking microcontroller 110 allows programming to set predetermined thresholds for the received failure signals.

The method also comprises sending 414 a wireless signal alarm if the failure signals are outside of the acceptable predetermined limits.

### Installation Instructions

The following are the installation instructions for the water leak detector described above.

1. Activate batteries.
2. Place sensor at lowest point near possible water source.
3. Insure the “MY LEAK” logo is facing up.
4. Open a browser on WIFI connected device.
5. Enter code from package into URL.
6. Find the local WIFI connection in the drop down box displayed.
7. Enter access code for WIFI.
8. Browser will redirect to Server LogIn.
9. Choose password.
10. Choose device just activated and enter location information, email address to use for notifications, phone number to use for text notifications.

In one embodiment, a system comprises one or more of: a water leak detector providing a water leak signal, a wireless networking microcontroller coupled to the water leak detector, the wireless networking microcontroller sending alarms based on the input from the water leak detector, a power conditioner coupled to the wireless networking microcontroller to provide a conditioned power signal to the wireless networking microcontroller and a programming interface coupled to the wireless networking microcontroller, wherein the programming interface provides conditioned programming signals to the wireless networking microcontroller to set predetermined alarm thresholds.

In another embodiment, a system comprises one or more of: a facilities failure detector providing a conditioned failure signal, a wireless networking microcontroller coupled to the facilities failure detector, the wireless networking microcontroller sending alarms based on the input from the facilities failure detector, a power conditioner coupled to the wireless networking microcontroller to provide a conditioned power signal to the wireless networking microcontroller and a programming interface coupled to the wireless networking microcontroller, wherein the programming interface provides conditioned programming signals to the wireless networking microcontroller to set predetermined alarm thresholds for the failure signal.

In a further embodiment, a method comprises one or more of: receiving conditioned failure signals from a facilities failure detector for a structure, determining whether the failure signals are within acceptable determined limits and sending a wireless signal alarm if the failure signals are outside of the acceptable predetermined limits.

During device setup the detector communication switches from a router to a client. This client switching simplifies communication in that the system sends data packets and does not receive external communication data packets. This simplification in communication from router to client disallows hijacking the detector by an external communication source.

Although an exemplary embodiment of at least one of a system, method, and non-transitory computer readable medium has been illustrated in the accompanied drawings and described in the foregoing detailed description, it will be understood that the application is not limited to the embodiments disclosed, but is capable of numerous rearrangements, modifications, and substitutions as set forth and defined by the following claims. For example, the capabilities of the system of the various figures can be performed by one or more of the modules or components described herein or in a distributed architecture and may include a transmitter, receiver or pair of both. For example, all or part of the functionality performed by the individual modules, may be performed by one or more of these modules. Further, the functionality described herein may be performed at various times and in relation to various events, internal or external to the modules or components. Also, the information sent between various modules can be sent between the modules via at least one of: a data network, the Internet, a voice network, an Internet Protocol network, a wireless device, a wired device and/or via plurality of protocols. Also, the messages sent or received by any of the modules may be sent or received directly and/or via one or more of the other modules. The system requires no dedicated internet connection hub, any wireless signal connection such as WiFi and the like may suffice for communication.

One skilled in the art will appreciate that a “system” could be embodied as a personal computer, a server, a console, a personal digital assistant (PDA), a cell phone that transceives a cellular signal, a tablet computing device, a smartphone or any other suitable computing device, or combination of devices. Presenting the above-described functions as being performed by a “system” is not intended to limit the scope of the present application in any way, but is intended to provide one example of many embodiments. Indeed, methods, systems and apparatuses disclosed herein may be implemented in localized and distributed forms consistent with computing technology.

It should be noted that some of the system features described in this specification have been presented as modules, in order to more particularly emphasize their implementation independence. For example, a module may be implemented as a hardware circuit comprising custom very large scale integration (VLSI) circuits or gate arrays, off-the-shelf semiconductors such as logic chips, transistors, or other discrete components. A module may also be implemented in programmable hardware devices such as field programmable gate arrays, programmable array logic, programmable logic devices, graphics processing units, or the like.

A module may also be at least partially implemented in software for execution by various types of processors. An identified unit of executable code may, for instance, comprise one or more physical or logic blocks of computer instructions that may, for instance, be organized as an object, procedure, or function. Nevertheless, the executables of an identified module need not be physically located together, but may comprise disparate instructions stored in different locations which, when joined logically together, comprise the module and achieve the stated purpose for the module. Further, modules may be stored on a computer-readable medium, which may be, for instance, a hard disk drive, flash device, random access memory (RAM), tape, or any other such medium used to store data.

Indeed, a module of executable code could be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network.

It will be readily understood that the components of the application, as generally described and illustrated in the figures herein, may be arranged and designed in a wide variety of different configurations. Thus, the detailed description of the embodiments is not intended to limit the scope of the application as claimed, but is merely representative of selected embodiments of the application.

One having ordinary skill in the art will readily understand that the above may be practiced with steps in a different order, and/or with hardware elements in configurations that are different than those which are disclosed. Therefore, although the application has been described based upon these preferred embodiments, it would be apparent to those of skill in the art that certain modifications, variations, and alternative constructions would be apparent.

While preferred embodiments of the present application have been described, it is to be understood that the embodiments described are illustrative only and the scope of the application is to be defined solely by the appended claims when considered with a full range of equivalents and modifications (e.g., protocols, hardware devices, software platforms etc.) thereto.

What is claimed is:

1. A system, comprising:
a water leak detector providing a water leak signal;
a wireless networking microcontroller coupled to the water leak detector, the wireless networking microcontroller sending alarms based on an input from the water leak detector;
a power conditioner coupled to the wireless networking microcontroller to provide a conditioned power signal to the wireless networking microcontroller; and
a programming interface coupled to the wireless networking microcontroller, wherein the programming interface provides programming signals to the wireless networking microcontroller to set predetermined alarm thresholds.

2. The system of claim 1, further comprising a first signal conditioner coupled to the programming interface and to the wireless networking microcontroller to condition the programming signals.

3. The system of claim 1, further comprising a second signal conditioner coupled to the water leak detector to condition the water leak signal.

4. The system of claim 1, further comprising a logic gate coupled to the wireless networking microcontroller to provide a logic signal.

5. The system of claim 1, wherein a wireless signal of the wireless networking microcontroller is a WiFi signal.

6. The system of claim 1, wherein a wireless signal of the wireless networking microcontroller is a cellular signal.

7. The system of claim 1, wherein a wireless signal of the wireless networking microcontroller is at least one of a ZigBee signal, a WiFi signal, a Bluetooth signal, a Bluetooth Low Energy signal and a WiMax signal.

8. A system, comprising:
a facilities failure detector providing a failure signal;
a wireless networking microcontroller coupled to the facilities failure detector, the wireless networking microcontroller sending alarms based on an input from the facilities failure detector;
a power conditioner coupled to the wireless networking microcontroller to provide a conditioned power signal to the wireless networking microcontroller; and
a programming interface coupled to the wireless networking microcontroller, wherein the programming interface provides programming signals to the wireless networking microcontroller to set predetermined alarm threshold for the failure signal.

9. The system of claim 8, wherein the facilities failure detector is a gas leak detector and the predetermined alarm threshold for the failure signal is a gas leak threshold.

10. The system of claim 8, wherein the facilities failure detector is a gas pressure detector and the predetermined alarm threshold for the failure signal is a gas pressure threshold.

11. The system of claim 8, wherein the facilities failure detector is a water pressure detector and the predetermined alarm threshold for the failure signal is a water pressure threshold.

12. The system of claim 8, wherein the facilities failure detector is an electrical voltage drop out detector and the predetermined alarm threshold for the failure signal is a voltage threshold.

13. The system of claim 8, wherein the facilities failure detector is an electrical spark detector and the predetermined alarm threshold for the failure signal is a spark threshold.

14. The system of claim 8, further comprising a first signal conditioner coupled to the programming interface and to the wireless networking microcontroller to condition the programming signals.

15. The system of claim 8, further comprising a second signal conditioner coupled to the facilities failure detector to condition the failure signal.

16. The system of claim 8, further comprising a logic gate coupled to the wireless networking microcontroller to provide a logic signal.

17. The system of claim 8, wherein a wireless signal of the wireless networking microcontroller is at least one of a ZigBee signal, a WiFi signal, a Bluetooth signal, a Bluetooth Low Energy signal and a WiMax signal.

18. A method comprising:
receiving failure signals from a facilities failure detector for a structure;
determining whether the failure signals are within acceptable predetermined limits; and
sending a wireless signal alarm if the failure signals are outside of the acceptable predetermined limits.

19. The method of claim 18, wherein the wireless signal alarm is at least one of a ZigBee signal, a WiFi signal, a Bluetooth signal, a Bluetooth Low Energy signal and a WiMax signal.

20. The method of claim 18, wherein the facilities failure detector is at least one of a gas leak detector, a gas pressure detector, a water leak detector, a water pressure detector, an electrical drop out detector and an electrical spark detector.
